(19) United States
(12) Patent Application Publication
(10) Pub. No.: US 2014/0199492 A1
(43) Pub. Date: Jul. 17, 2014

(54) ION IMPLANTER AND METHOD OF OPERATING ION IMPLANTER

(71) Applicant: NISSIN ION EQUIPMENT CO., LTD., Kyoto-shi (JP)

(72) Inventor: Takeshi MATSUMOTO, Kyoto (JP)

(73) Assignee: NISSIN ION EQUIPMENT CO., LTD., Kyoto-shi (JP)

(21) Appl. No.: 14/063,373

(22) Filed: Oct. 25, 2013

(30) Foreign Application Priority Data
Jan. 16, 2013 (JP) 2013-005803

(51) Int. Cl. C23C 14/48

(52) U.S. Cl. CPC C23C 14/48
USPC 427/523; 118/723 R

(57) ABSTRACT

An ion implanter that introduces a process gas into an ion source, extracts a ribbon-shaped ion beam from the ion source using an extraction electrode system made up of multiple electrodes, and uses the ion beam to irradiate a substrate disposed in a processing chamber during ion implantation processing, and that also introduces a cleaning gas into the ion source and performs cleaning inside said ion source at times other than during ion implantation processing, wherein during the re-initiation of the ion beam upon termination of cleaning, a predetermined voltage is applied to the extraction electrode system and the operating parameters of the ion source are then set to values corresponding to the implantation recipe of the substrate to be processed.

### CROSS-REFERENCE TO RELATED APPLICATION

This application claims foreign priority under 35 USC 119 to Japanese Patent Application No. 2013-5803, the content of which is incorporated herein by reference in its entirety.

### BACKGROUND

1. Technical Field

Aspects of the present example implementation relates to an ion implanter that performs ion implantation processing on silicon wafers or glass substrates by irradiating said wafers or substrates with an ion beam, and more particularly, to an ion implanter with a cleaning capability, as well as to a method of operating said ion implanter.

2. Related Art

If an ion implanter extracting an ion beam from an ion source is operated for an extended period of time, deposits adhere to the electrodes forming part of the extraction electrode system of the ion source, and to the plasma-generating vessel forming part of the ion source. If this is allowed to continue, abnormal electric discharges are generated between the electrodes of the extraction electrode system.

If the frequency of occurrence of such abnormal electric discharges increases, the inside of the ion source must be cleaned on an as-needed basis, because it otherwise becomes impossible to keep the ion source operating normally.

As an example of such cleaning, Patent Document 1 discloses a technique in which deposits on the inside of an ion source are cleaned by introducing hydrogen gas into the ion source and generating a hydrogen plasma in the ion source at times other than during the implantation of ions into samples.

### RELATED ART

### Patent Literature

[Patent Citation 1] Japanese Patent No. 2956412

### SUMMARY

### Problems to be Addressed

The technique of Patent Citation 1 describes cleaning carried out by generating hydrogen plasma inside an ion source at times other than during the implantation of ions into samples, but gives no indication as to how the ion beam is re-initiated thereafter.

In an ion implanter, the operation of ion implantation processing on multiple substrates is performed multiple times in separate batches containing a predetermined number of substrates. In order to exchange processed substrates for unprocessed substrates between individual ion implantation operations, ion implantation processing on the substrates is momentarily stopped. Although it has been contemplated to clean the inside of an ion source during such substrate exchanges based on the technology described in Patent Citation 1, in such a case, the ion beam needs to be initiated within a short period of time after cleaning, because normally the substrate exchange takes at most only a few minutes.

Accordingly, the present example implementation provides an ion implanter capable of re-initiating the ion beam within a short period of time after cleaning, and a method of operating the implanter.

### Means for Addressing the Problems

The inventive ion implanter, which is an ion implanter that introduces a process gas into an ion source, extracts a ribbon-shaped ion beam from the ion source using an extraction electrode system made up of multiple electrodes, and uses the ion beam to irradiate a substrate disposed in a processing chamber during ion implantation processing, and that introduces a cleaning gas into the ion source and performs cleaning inside said ion source at times other than during ion implantation processing, is provided with a controller which, during the re-initiation of the ion beam upon termination of cleaning, applies a voltage (e.g., predetermined) to the extraction electrode system and then sets the operating parameters of the ion source to operating parameters corresponding to the implantation recipe of the substrate to be processed.

Although the application of a voltage (e.g., a predetermined voltage) to the extraction electrode system creates an electric field distribution (e.g., predetermined) between the electrodes, the system goes through a transient state before this electric field distribution is established. If plasma with a density equal to that of the plasma generated during ion implantation processing is generated in the ion source while the electric field between the electrodes is in a transient state, an ion beam with an ion beam current comparable to the one used during implantation is extracted from this plasma, and a large portion thereof collides with the extraction electrode system. In particular, since the ion beam current generated when extracting a ribbon-shaped ion beam is much higher than that of a spot-shaped ion beam, such collisions of the ion beam with the extraction electrode system cause overcurrents to flow to the power supplies used to apply voltages to the extraction electrode system. These overcurrents destabilize the output voltages of the power supplies and make it impossible to perform the desired ion beam initiation within a short period of time.

In light of the foregoing, the present example implementation uses a configuration provided with a controller which, during ion beam re-initiation, applies a voltage (e.g., a predetermined voltage) to the extraction electrode system and then sets the operating parameters of the ion source to operating parameters corresponding to the implantation recipe of the substrate to be processed. As a result, it is possible to sufficiently suppress collisions between the extraction electrode system and an ion beam that has a relatively high ion beam current because after the formation of an electric field (e.g., a predetermined electric field) between the electrodes that constitute the extraction electrode system, plasma is generated that has a density equal to that of the plasma generated in the ion source during ion implantation processing, and an ion beam can be extracted therefrom. As a result, at no time do overcurrents flow to the power supplies connected to the extraction electrode system and the initiation of the ion beam can be accomplished within a short period of time.

In an ion implanter that performs ion implantation processing on a plurality of substrates multiple times in separate batches containing a number of substrates (e.g., a predetermined number of substrates), the above-mentioned controller performs cleaning inside the ion source at least once before all the ion implantation operations are complete.

If such a configuration is adopted, ion source cleaning can be performed during time gaps in a series of consecutive ion implantation operations, and it is therefore not necessary to stop the operation of the ion implanter in order to clean the ion source.

In addition, it is possible to prevent the generation of plasma in the ion source during the application of a voltage (e.g., a predetermined voltage) to the extraction electrode system at the time of ion beam re-initiation.

If plasma is generated in the ion source during the application of a voltage (e.g., predetermined) to the extraction electrode system, an undesirable ion beam is extracted therefrom. At such time, there is a risk that a large portion of the ion beam extracted under the action of transient electric fields may collide with the extraction electrode system. When the density of the plasma is sufficiently low, a high-current ion beam is not extracted, thereby eliminating problems such as overcurrents flowing to the power supplies connected to the extraction electrode system and the destabilization of the output voltages of the power supplies. However, the following concerns arise as a result of collisions between the extraction electrode system and the ion beam.

As the ion beam collides with the extraction electrode system, the deposits on the extraction electrode system are sputtered, and this causes discharges between the electrodes constituting the extraction electrode system. In addition, device yields may be reduced if the sputtered deposits are scattered on the downstream side of the travel path of the ion beam and contaminate the substrate. However, if the generation of plasma in the ion source during the application of the voltage (e.g., predetermined voltage) to the extraction electrode system is avoided, the above-described collision of the ion beam with the extraction electrode system can be prevented.

In a more specific ion source configuration, the ion source is provided with a plasma-generating vessel into which the cleaning gas and process gas are introduced and where plasma is generated. Inside the plasma-generating vessel, there are disposed one, two, or more cathodes and, between the cathode and the plasma-generating vessel, there is connected a power supply that regulates the potential difference between the two members.

In addition, during the re-initiation of the ion beam, the controller sets the output voltages of the power supplies connected to the extraction electrode system to predetermined levels and then sets the output voltage of the power supply connected between the cathode and the plasma-generating vessel to a level (e.g., predetermined).

Furthermore, in the inventive method of operating an ion implanter, in which said ion implanter is an ion implanter that introduces a process gas into an ion source, extracts a ribbon-shaped ion beam from the ion source using an extraction electrode system made up of multiple electrodes, and uses the ion beam to irradiate a substrate disposed in a processing chamber during ion implantation processing, and that also introduces a cleaning gas into the ion source and performs cleaning inside said ion source at times other than during ion implantation processing, during the re-initiation of the ion beam upon termination of cleaning, a predetermined voltage is applied to the extraction electrode system and the operating parameters of the ion source are then set to operating parameters corresponding to the implantation recipe of the substrate to be processed.

### Effects

It is possible to sufficiently suppress collisions between the extraction electrode system and an ion beam that has a relatively high ion beam current because the implanter is adapted to change the operating parameters of the ion source to operating parameters corresponding to the implantation recipe of the substrates to be processed once the distribution of the electric field between the electrodes matches a value (e.g., a predetermined value). As a result, at no time do overcurrents flow to the power supplies connected to the extraction electrode system and the initiation of the ion beam can be accomplished within a short period of time.

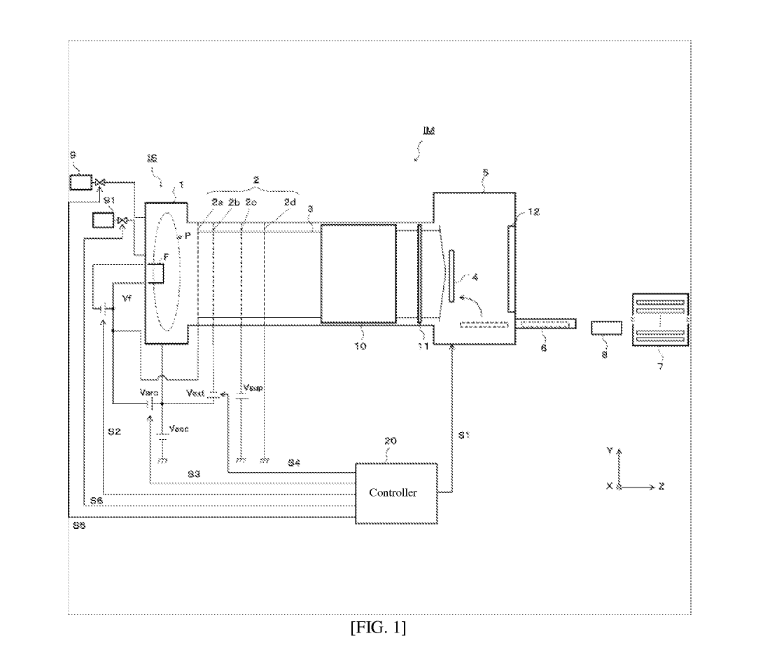

### BRIEF DESCRIPTION OF THE DRAWINGS

[FIG. 1]

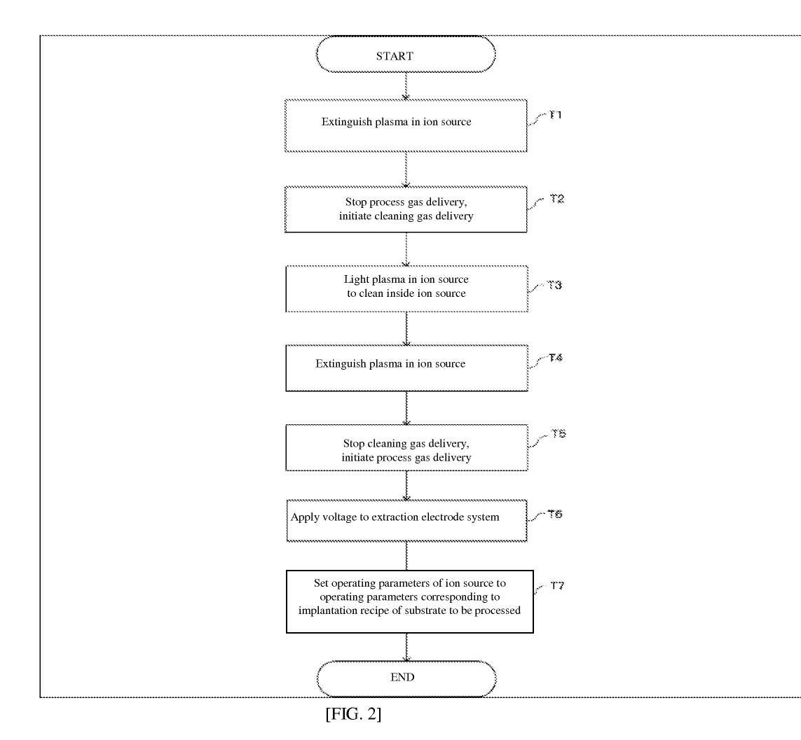

A plan view of an ion implanter IM according to an example implementation. [FIG. 2]

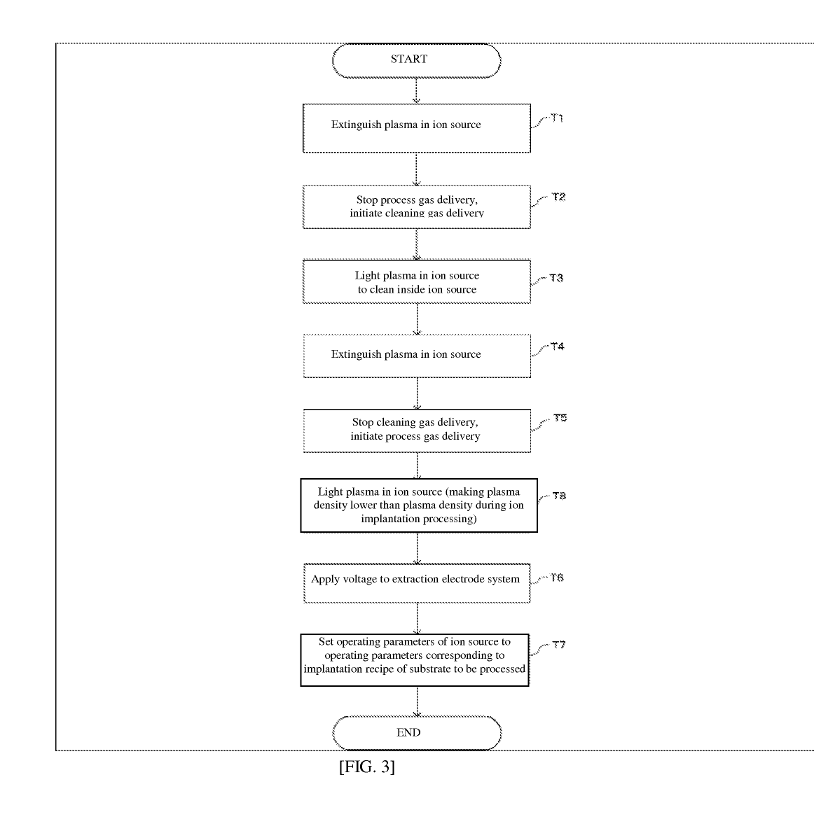

A flow chart representing a first processing example illustrating ion beam re-initiation.

[FIG. 3]

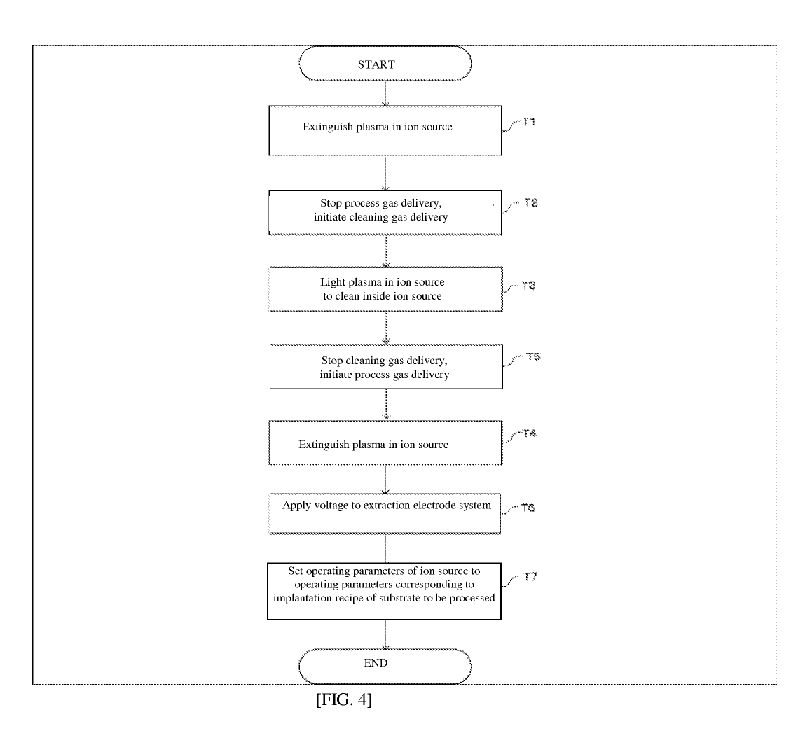

A flow chart representing a second processing example illustrating ion beam re-initiation.

[FIG. 4]

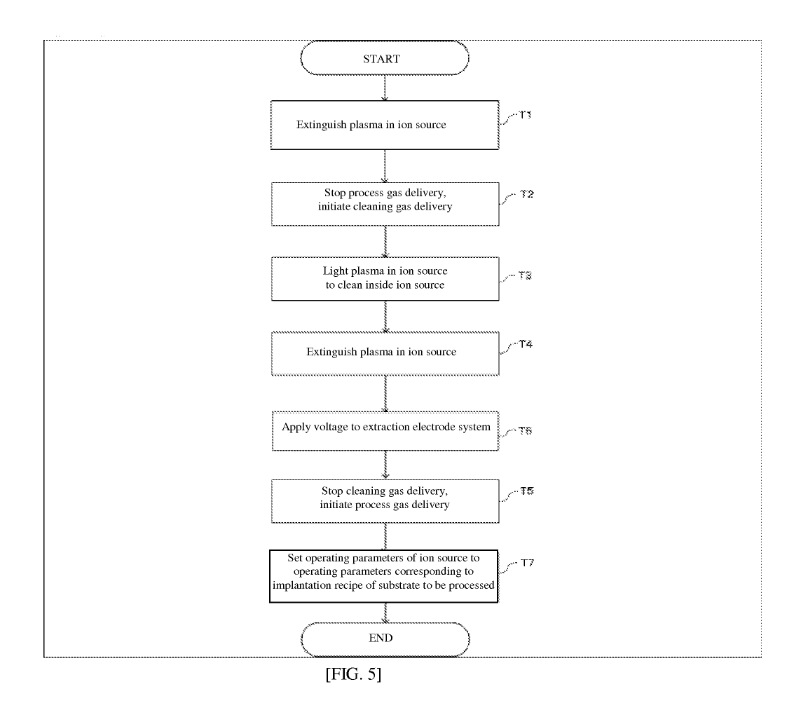

A flow chart representing a third processing example illustrating ion beam re-initiation.

[FIG. 5]

A flow chart representing a fourth processing example illustrating ion beam re-initiation.

### DETAILED DESCRIPTION OF EXAMPLE IMPLEMENTATIONS

The example ion implanter and method of operating the same are described below with reference to drawings.

A plan view of an example ion implanter IM is depicted in FIG. 1. The configuration of the entire ion implanter IM is briefly explained below. It should be noted that the illustrated X-axis, Y-axis, and Z-axis directions are mutually orthogonal.

The plasma-generating vessel 1 is a substantially cube-shaped container illustrated such that its size in the Y-axis direction is greater than its size in the X-axis direction. A process gas (BF₃ or PH₃, etc., but not limited thereto) is delivered to the container from a first gas cylinder 9. In addition, the electric potential of the plasma-generating vessel 1 is set to a predetermined level by an acceleration power supply Vacc. Furthermore, a cathode F is placed inside the plasma-generating vessel 1 and a potential difference, which may be predetermined, is set between the cathode F and the plasma-generating vessel 1 with the help of an arc power supply Varc. It should be noted that an insulator, not shown, is provided between the cathode F and the plasma-generating vessel 1 and these two members are electrically isolated by this insulator.

A cathode power supply Vf is connected to both ends of the cathode F and thermionic electrons are emitted from the cathode F heated by this power supply. When the thermionic electrons collide with the process gas delivered from the first gas cylinder 9, the process gas is ionized, generating a plasma P.

An aperture is provided in the side of the plasma-generating vessel 1 that faces in the Z-axis direction and an extraction electrode system 2 used for extracting a ribbon-shaped ion beam 3 (in this example, an ion beam whose size in the Y-axis direction is longer than in the X-axis direction) from the plasma P is disposed therein. The extraction electrode system 2 is made up of multiple electrodes, for example four electrodes as depicted in FIG. 1. Starting from the plasma-generating vessel 1, an acceleration electrode 2a, an extraction electrode 2b, a suppression electrode 2c, and a ground electrode 2d are disposed side by side in that order while being electrically isolated from one another. A single slit, a plurality of slits, or a plurality of round holes are formed in these electrodes to let the ion beam 3 through. Further, other structures that let the ion beam 3 through, as would be known to those skilled in the art, may be substituted therefor without departing from the inventive scope.

In this example, the acceleration electrode 2a has the same electric potential as the cathode F and the ground electrode 2d is electrically grounded. In addition, a suppression power supply Vsup applying a negative voltage to the electrodes is connected to the suppression electrode 2c in order to prevent an electron flow from the Z-axis direction, in which the ion beam 3 is extracted, towards the plasma-generating vessel 1.

After mass analysis using an analyzer magnet 10 and an analyzer slit 11, the ion beam 3 extracted from extraction electrode system 2 is directed into the processing chamber 5.

A substrate 4 is transported by a transport robot 8 from a cassette 7, which is located outside the processing chamber 5, into a load lock chamber 6. When the substrate 4 is transported to the load lock chamber 6, a pump (not shown) evacuates atmosphere from the load lock chamber 6, which is placed under a vacuum. Then, after reaching a degree (e.g., predetermined) of vacuum, a door in the load lock chamber 6 opens into the processing chamber 5 and the substrate 4 is transported into the processing chamber 5. It should be noted that when the load lock chamber 6 is evacuated, the door of the load lock chamber 6 that faces towards the atmosphere (where the cassette 7 is located) is closed.

The attitude of the substrate 4 transported into the processing chamber 5 is changed by a tilting mechanism (not shown) such that the surface irradiated by the ion beam 3 becomes generally parallel to the Y-axis direction. After that, the substrate 4 is scanned while being moved in the X-axis direction by a transport mechanism (not shown). It should be noted that when the substrate 4 is scanned, the substrate 4 may cross the ion beam 3 once or many times. In addition, the direction of scanning of the substrate 4 may be different from the X-axis direction. In other words, it may be a direction orthogonal to the Z-direction, i.e. the direction of travel of the ion beam 3, or any direction as long as ion implantation is performed across the entire surface of the substrate 4 as a result of scanning the substrate 4.

As shown in the figure, the size of the ion beam 3 in the Y-axis direction is longer than the size of the substrate 4. For this reason, due to the fact that the substrate 4 is scanned in the X-axis direction, ion implantation is performed across the entire surface of the substrate 4. After ion implantation processing on the substrate 4, the substrate 4 follows a path opposite to the path used for transportation to the processing chamber 5 and is stored in the cassette 7. In addition, in the processing chamber 5, there is provided an ion beam measurement apparatus 12, which is used to check whether the ion beam 3 has the desired characteristics prior to the irradiation of the substrate 4 with the ion beam 3.

After storing the processed substrate in the cassette 7, an unprocessed substrate is removed from the cassette 7 by the transport robot 8 and is again transported into the processing chamber 5, whereupon ion implantation processing is performed on the substrate 4. Such exchanges of processed substrates and unprocessed substrates are repeated until ion implantation processing on multiple substrates stored in the cassette 7 is complete.

There are no substrates 4 to be processed in the processing chamber 5 when a substrate exchange is performed, and there is therefore, there is no need to operate the ion beam 3 for irradiation. In the present example implementation, the cleaning of the ion source IS is performed at least once during the multiple substrate exchanges carried out in a series of repeated ion implantation operations.

A controller 20 is provided in the ion implanter IM. The function of the controller 20 is to control the scanning of the substrate 4 using a transport mechanism (not shown) by transmitting a signal S1. The controller 20 controls the transport mechanism and possesses information on the location of the substrate 4. Based on this location information, the controller transmits signals S2-S6 to the cathode power supply Vf, arc power supply Varc, extraction power supply Vext, first gas cylinder 9, and second gas cylinder 91 in order to control each unit. In addition, when the output voltage level of the acceleration power supply Vacc is subject to control, control signals intended for its power supply are also transmitted.

A number of processing methods are contemplated for the period from the end of ion implantation processing of the substrate 4 to the cleaning of the inside of the ion source IS and, after the cleaning, until the re-initiation of the ion beam 3. A common feature of these methods is that when the ion beam 3 is re-initiated after cleaning, first of all, a predetermined voltage (e.g., a voltage set for ion implantation processing on the substrate 4) is applied to the electrodes by the power supplies (in the example of FIG. 1, the extraction power supply Vext and suppression power supply Vsup) connected to the extraction electrode system 2.

Next, the operating parameters of the ion source IS are set to operating parameters corresponding to the implantation recipe of the substrate 4 to be processed. While the operating parameters of the ion source IS vary depending on the configuration of the ion source IS, in the example of FIG. 1, the output voltage level of the arc power supply Varc, the output voltage level of the cathode power supply Vf, the output voltage level of the acceleration voltage Vacc, the flow rate of the process gas from the first gas cylinder 9, and the flow rate of the cleaning gas from the second gas cylinder 91 constitute the parameters corresponding to the operating parameters of the ion source IS.

When the substrate 4 undergoes ion implantation, the implantation recipe is determined in accordance with the type of the substrate 4 and the type of the implantation process. As used herein, the term “implantation recipe” refers to the dose injected into the substrate 4, ion species, and ion beam energy. Of these, the dose is determined by the speed at which the substrate 4 is scanned and the ion beam current of the ion beam 3 used to irradiate the substrate 4.

In the example of FIG. 1, the ion beam current is determined by the level of the voltage applied to the extraction electrode system 2 and the density of the plasma in the ion source IS, and the density of the plasma is determined by the output voltage level of the arc power supply Varc, the output voltage level of the cathode power supply Vf, the output voltage level of the acceleration power supply Vacc, the flow rate of the process gas delivered from the first gas cylinder 9, and the flow rate of the cleaning gas delivered from the second gas cylinder 91.

As described above, the system is adapted to apply a predetermined voltage (a voltage set for ion implantation processing on the substrate 4) to the extraction electrode system 2 by the power supplies (in the example of FIG. 1, extraction power supply Vext and suppression power supply Vsup) connected to the extraction electrode system 2 and then set the operating parameters of the ion source IS to operating parameters corresponding to the implantation recipe of the substrate 4 to be processed. For this reason, when the ion beam 3 is re-initiated, it is possible to sufficiently suppress collisions between the extraction electrode system 2 and the ion beam 3, which has a relatively high ion beam current.

The collisions of the extraction electrode system 2 with the ion beam 3 occur in the following manner. Although the application of a voltage to the extraction electrode system 2 creates a predetermined electric field distribution between the electrodes, the system goes through a transient state before such an electric field distribution is established. If a plasma P with a density equal to that of the plasma generated during ion implantation processing is generated in the ion source IS while the electric field between the electrodes is in a transient state, an ion beam 3 with an ion beam current comparable to the one used during ion implantation is extracted from this plasma P, and a large portion thereof collides with the extraction electrode system 2.

In particular, when a ribbon-shaped ion beam 3 is extracted, the ion beam current is much higher than that of a spot-shaped ion beam. For this reason, as the extraction electrode system 2 collides with such a ribbon-shaped ion beam 3, overcurrents flow to the power supplies used to apply voltages to the extraction electrode system 2. The overcurrents destabilize the output voltages of the power supplies and make it impossible to perform the desired initiation of the ion beam 3 within a short period of time.

In light of the foregoing, the example implementation uses a configuration in which, during the re-initiation of the ion beam 3, a voltage (e.g., a predetermined voltage) is applied to the extraction electrode system 2, whereupon the operating parameters of the ion source IS are set to operating parameters corresponding to the implantation recipe of the substrates to be processed. As a result, it is possible to sufficiently suppress collisions between the extraction electrode system 2 and an ion beam 3 that has a relatively high ion beam current because after the formation of an electric field (e.g., predetermined) between the electrodes that constitute the extraction electrode system 2, there is generated a plasma P that has a density equal to that of the plasma P generated in the ion source IS during ion implantation processing, and an ion beam 3 can be extracted therefrom. As a result, this has the effect that at no time do overcurrents flow to the power supplies connected to the extraction electrode system and the initiation of the ion beam can be accomplished within a short period of time.

Between the re-initiation of the ion beam 3 and the start of actual ion implantation processing on the substrate 4, the ion beam measurement apparatus 12 measures the ion beam current of the ion beam 3 extracted from the extraction electrode system 2. If the desired ion beam current is obtained, ion implantation processing on the substrate 4 is performed right away. However, if the desired ion beam current is not obtained, the above-described operating parameters of the ion source IS and the voltages applied to the extraction electrode system 2 are fine-tuned.

Specific examples of processing during the period from the end of ion implantation processing on the substrate 4 to the cleaning of the inside of the ion source IS and, after the cleaning, until the re-initiation of the ion beam 3 are explained below with reference to FIGS. 2-5.

FIG. 2 describes a first processing example. Since ion implantation processing on the substrate 4 has been completed, at T1, the plasma P inside the ion source IS is extinguished. Next, at T2, the delivery of the process gas by the first gas cylinder 9 is stopped and the delivery of the cleaning gas by the second gas cylinder 91 is initiated. Because the ion implanter IM is provided with a vacuum pump (not shown) and the implanter is evacuated to a vacuum by the vacuum pump, the residual gas remaining after the delivery of the process gas stops is discharged from the implanter by the pump. In addition, as the delivery of the cleaning gas is stopped, as described below, the cleaning gas remaining in the ion source IS is also discharged from the apparatus by the above-mentioned vacuum pump.

At T3, the plasma P is lit inside the ion source IS to effect cleaning of the inside of the ion source IS using this plasma P. It should be noted that the plasma P generated therein uses the cleaning gas as a raw material. In addition, the lighting and extinguishing of the plasma P is performed by the controller 20 by setting the output voltages of the cathode power supply Vf and arc power supply Varc to levels that may be predetermined levels. Furthermore, since there is no need to extract the ion beam 3 when cleaning the inside of the ion source IS, the controller 20 sets the output voltage of at least the extraction power supply Vext either to zero or to a level at which the ion beam 3 is not extracted. The hereinafter described examples of FIGS. 3-5 are similar in these respects.

At T4, the cleaning gas-derived plasma P is extinguished. After that, at T5, the delivery of the cleaning gas by the second gas cylinder 91 is stopped and, at the same time, the delivery of the process gas by the first gas cylinder 91 is initiated. It should be noted that in the example of FIG. 2, the output voltage levels of the cathode power supply Vf and arc power supply Varc at time T5 are set either to zero or to a level at which the plasma P in the ion source IS cannot be lit.

Next, at T6, a voltage (e.g., a predetermined voltage) is applied to the electrodes constituting the extraction electrode system 2. The voltage level used at such time is the voltage level set for ion implantation processing on the substrate 4, which is determined in advance in accordance with the implantation recipe of the substrate 4 to be processed. Subsequently, at T7, the operating parameters of the ion source IS are set to values corresponding to the implantation recipe of the substrate 4 to be processed. Specifically, the volume of the process gas delivered by the first gas cylinder 9 is set to a level (e.g., a predetermined level) and the volume of the cleaning gas delivered by the second gas cylinder 91 is set to zero. In addition, the voltage output of the cathode power supply Vf and arc power supply Varc are set to predetermined levels. Furthermore, if the output voltage level of the acceleration power supply Vacc changes between the end of the previous ion implantation process and the re-initiation of the ion beam 3, it is reset back to the level (e.g., predetermined) used in the ion implantation process.

As a result of performing processing at T7, a process gas-derived plasma P with a predetermined density is generated in the ion source IS and an ion beam 3 that has an ion beam current equal to that of the ion beam 3 used in ion implantation processing on the substrate 4 can be extracted therefrom.

A second processing example is depicted in FIG. 3. In the processing examples depicted in FIG. 3 and in the hereinafter described FIG. 4 and FIG. 5, processing operations designated by the same symbols as the ones used in the processing example of FIG. 2 are the same operations as the operations described in FIG. 2. For this reason, when FIG. 3-FIG. 5 are described, the emphasis is on operations different from the operations depicted in FIG. 2.

The difference between the processing example of FIG. 2 and the processing example of FIG. 3 is whether a processing operation is performed at T8. In the example of FIG. 3, before plasma P of a predetermined density is generated at T7, plasma P of a lower density is lit at T8. The lighting of this plasma P is performed by controlling the output voltage levels of the cathode power supply Vf and arc power supply Varc with the help of the controller 20, but the density of the plasma P lit at this point is sufficiently low in comparison with the density of the plasma P generated in the ion source IS when ion implantation processing is performed on the substrate 4.

As shown in the example of FIG. 3, such low-density plasma P may remain lit until the ion beam re-initiation process is complete. In such a configuration, a large portion of the ion beam 3 extracted from the low-density plasma P collides with the electrodes constituting the extraction electrode system 2 under the action of transient electric fields when at T6 a voltage (e.g., predetermined) is applied to the electrodes of the extraction electrode system 2, but because the ion beam current of the extracted ion beam 3 is low due to the sufficiently low density of the plasma P, problems such as overcurrents flowing to the power supplies connected to the extraction electrode system 2 and the destabilization of the output voltages of the power supplies do not arise.

However, as the ion beam 3 extracted from such low-density plasma P collides with the extraction electrode system, the deposits deposited on the extraction electrode system 2 are subjected to sputtering and there is a risk that discharges may be generated between the electrodes constituting the extraction electrode system 2. In addition, substrate implantation fails if the sputtered deposits are scattered on the downstream side of the travel path of the ion beam 3 and contaminate the substrate 4.

In view of the foregoing, instead of the approach depicted in FIG. 3, the approach described in FIG. 2 may be implemented, in which the plasma P inside the ion source IS is extinguished before a voltage (e.g., predetermined) is applied to the electrodes of the extraction electrode system 2.

A third processing example is depicted in FIG. 4. The difference from the processing example of FIG. 2 is that the order of processing of T4 and T5 is reversed. In the processing example of FIG. 4, at T3, after cleaning the inside the ion source IS, the cleaning gas-derived plasma in the ion source IS is lit, and at T5, the delivery of the cleaning gas by the second gas cylinder 91 is stopped and the delivery of the process gas by the first gas cylinder 9 is initiated. After that, the plasma P in the ion source IS is extinguished.

A fourth processing example is depicted in FIG. 5. The difference from the processing example of FIG. 2 is that the order of processing of T5 and T6 is reversed. In the processing example of FIG. 5, after a voltage (e.g., predetermined) is applied to the electrodes of the extraction electrode system 2, the delivery of the cleaning gas is stopped and the delivery of the process gas is initiated. As shown in the processing example of FIG. 5, the timing of process gas delivery may be different from the processing example of FIG. 2.

### <Other Variations>

Although in the processing examples of FIG. 2-FIG. 5 the implanter is adapted to stop the delivery of the cleaning gas simultaneously with the start of process gas delivery, these operations may be performed separately. For example, in the processing example of FIG. 2, the apparatus may be adapted to stop the delivery of the cleaning gas by the second gas cylinder 91 when the plasma is extinguished in the ion source at T4, and after that, start the delivery of the process gas by the first gas cylinder 9 as part of processing at T5.

Although in the configuration of the ion implanter IM depicted in FIG. 1 there is only one gas cylinder filled with the process gas, i.e. the first gas cylinder 9, multiple gas cylinders filled with various types of process gas may be provided for use in accordance with the implantation recipe of the substrate 4. For example, a cylinder filled with BF3 and a cylinder filled with PH3 may be separately provided, and if the ion species in the implantation recipe of the substrate 4 is B, the process gas is delivered from the gas cylinder filled with BF3.

In addition, although in the configuration of the ion implanter IM depicted in FIG. 1 there is only one cathode F disposed inside the plasma-generating vessel 1 of the ion source IS, there may be more than one cathode F. If multiple cathodes F are provided, then a single cathode power supply Vf may be shared by the cathodes F. Alternatively, an individual cathode power supply Vf may be provided for each cathode F in order to be able to control the multiple cathodes F on an individual basis.

Furthermore, the ion source IS may be an ion source of the conventional indirectly heated type known in the art, or an ion source of the HF type.

In addition, there may be either one or multiple substrates subjected to ion implantation processing at one time.

Other than as described above, various improvements and modifications may of course be made without departing from the basic inventive concept.

We claim:

1. An ion implanter that introduces a process gas into an ion source, extracts a ribbon-shaped ion beam from the ion source using an extraction electrode system made up of a plurality of electrodes, and uses the ion beam to irradiate a substrate disposed in a processing chamber during ion implantation processing, and that introduces a cleaning gas into the ion source and performs cleaning inside the ion source at times other than during ion implantation processing, wherein:
the ion implanter comprises a controller which, during the re-initiation of the ion beam upon termination of cleaning, applies a voltage to the extraction electrode system and sets the operating parameters of the ion source to operating parameters corresponding to the implantation recipe of the substrate to be processed.

2. The ion implanter according to claim 1, configured to perform ion implantation processing on a plurality of substrates a plurality of times in separate batches containing a number of substrates, wherein:
the controller performs the cleaning inside the ion source at least once before all the ion implantation operations are complete.

3. The ion implanter according to claim 1, wherein plasma is not generated in the ion source during the application of the voltage to the extraction electrode system at the time of the re-initiation of the ion beam.

4. The ion implanter according to claim 1, further comprising:
the ion source being provided with a plasma-generating vessel into which the cleaning gas and the process gas are introduced and in which plasma is generated,
one or more cathodes disposed in the plasma-generating vessel, and a power supply that regulates the potential difference between the cathode and the plasma-generating vessel, the power supply being connected between the two members.

5. The ion implanter according to claim 4, wherein during the re-initiation of the ion beam, the controller sets the output voltages of the power supplies connected to the extraction electrode system to levels and then sets the output voltage of the power supply connected between the cathode and the plasma-generating vessel to a level.

6. A method for operating an ion implanter that introduces a process gas into an ion source, extracts a ribbon-shaped ion beam from the ion source using an extraction electrode system made up of a plurality of electrodes, and uses the ion beam to irradiate a substrate disposed in a processing chamber during ion implantation processing, and that introduces a cleaning gas into the ion source and performs cleaning inside said ion source at times other than during ion implantation processing, wherein:
during the re-initiation of the ion beam upon termination of cleaning, a voltage is applied to the extraction electrode system and the operating parameters of the ion source are then set to values corresponding to the implantation recipe of the substrate to be processed.
